(19) United States
(12) Patent Application Publication
(10) Pub. No.: US 2008/0093630 A1
(43) Pub. Date: Apr. 24, 2008

(54) Heterostructure Field Effect Transistor

(75) Inventors: Hassan Maher, Boissy-St-Leger (FR); Pierre M.M. Baudet, Yerres (FR)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/571,671

(22) PCT Filed: Jul. 6, 2005
(86) PCT No.: PCT/IB05/52249

§ 371 Date: Jan. 5, 2007

(30) Foreign Application Priority Data
Jul. 8, 2004 (EP) 04300433.2

(51) Int. Cl. H01L 29/778; H01L 21/338

(52) U.S. Cl. 257/192; 438/172; 257/E29.246; 257/E21.403

(57) ABSTRACT

A HEMT has a substrate (2), buffer layer (4), channel layer (8), spacer layer (10), delta doped layer (12), Schottky barrier layer (14) and cap layer (18) and metal layer (20), the latter forming a Schottky barrier with the underlying semiconductor. The channel may be of GaInAs and the barrier (4), spacer (10) and Schottky barrier layers (14) may be of AlInAs. An additional thin layer for example of GaAs is added between the Schottky barrier layer (14) and metallic layer (18) to enhance the Schottky barrier height without creating excessive defects.

The invention relates to a heterostructure field effect transistor (HFET), and in particular but not exclusively to a high electron mobility transistor (HEMT).

In a typical HFET, a metal gate contact forms a Schottky barrier with a Schottky barrier semiconductor layer over a channel semiconductor layer, the channel semiconductor layer forming a heterostructure with the Schottky barrier semiconductor layer. Source and drain contacts are provided on either side of the gate. The voltage on the metal gate contact controls conduction in the channel between the source and drain contacts. Note that the Schottky barrier layer may include in particular a delta doped layer near the channel to provide carriers in the channel.

In an HFET the Schottky barrier height is an important parameter which determines the threshold forward voltage and the gate leakage current, made up of thermo-ionic and tunnel currents. These have a major influence on the properties of an HFET and have a great effect on performance, in particular the pinch-off voltage, the breakdown voltage, output conductance, gain cut-off frequency, noise, and many more.

A Schottky barrier is a barrier between a metal material and a semiconductor. Different metals may be used as Schottky gate metals in HFETs, such as titanium, molybdenum, platinum and palladium. Platinum has the highest work function, which leads to a Schottky barrier height of 1.05V. Platinum is suitable for a large surface area Schottky diode but is unsuitable for use in high performance submicron HFETs due to poor adhesion. Further, where AlInAs is present, a further problem occurs in that platinum reacts with AlInAs at relatively low temperatures (about 250° C.) and may diffuse, even during device operation. This would result in device unreliability. For these reasons, titanium is often the preferred metal.

The semiconductor also has an effect on the Schottky barrier height, generally a greater effect than the metal. In particular, the pinning of the Fermi level in the semiconductor at the surface of the semiconductor before deposition of metal generally is highly significant. In general, wider band gap semiconductors result in higher Schottky barriers. Various semiconductors such as InP, AlInAs, AlGaAs, AlInP and GaInP have all been used as a Schottky contact layer.

A standard InP HEMT generally uses a lattice matched layer of Al_{0.48}In_{0.52}As as a Schottky barrier layer and Ti as a contact metal. This gives a Schottky barrier height of about 0.65 eV±0.05 eV. InP is less suitable as a Schottky layer since although it is lattice matched it gives a low Schottky barrier height (about 0.42 eV).

Alternatively, a mismatched layer of semiconductor may be used as the Schottky barrier layer, but this generates a lot of traps and defects in the volume and interface of the semiconductor that adversely affect the transistor performance.

For these reasons, the standard AlInAs lattice matched to the substrate makes a good choice for the barrier layer.

A problem exists however with AlInAs since the high Al content may form a native oxide layer before the gate metal is formed. This affects both gate current leakage and device reliability.

It has been proposed to deoxidize the surface before metallisation using an Ar plasma to solve this problem, but the plasma itself generates defects affecting the quality of the barrier layer especially when using a thin barrier.

There thus remains a need for an improved Schottky gate for a HFET, especially in high In content channel FETs.

According to the invention there is provided an HFET according to claim 1.

The use of an additional layer of a further semiconductor material giving a higher Schottky barrier improves the properties of the gate contact. However, because the layer is thin it can easily be grown with good quality even though it does not in general have a lattice constant that matches the substrate or the other semiconductor material layers.

Further, the manufacture of the device is easy to integrate into existing processes.

Preferably, the thickness of the strained semiconductor layer is in the range 2 nm to 6 nm.

The first semiconductor material may be GaInAs and the second semiconductor material layer may be of AlInAs. The third semiconductor material layer may be of GaAs. The substrate may be of InP or GaInAs. In particularly preferred embodiments, the second material layer may be of Al_{0.48}In_{0.52}As and the substrate InP which have matching lattice constants.

The proposed HFET has many advantages. The Schottky barrier height is about 0.8 eV rather than the 0.65 eV without the intermediate layer.

Further, the GaAs does not contain any aluminum and the device is therefore more reliable than AlInAs since the GaAs surface is less susceptible to oxidation prior to metallisation.

Note that the positive step on the conduction band between GaAs and AlInAs increases the Schottky barrier height.

Preferably, a cap layer of semiconductor is formed on the intermediate layer, and etched to expose the intermediate layer in the gate region. InGaAs can be more selectively etched on GaAs than on AlInAs. Since InGaAs cap layers are often used, the GaAs intermediate layer makes the etching step easier. Source and drain contacts may be formed on the cap layer.

A large forward swing can be achieved in an enhancement mode FET in accordance with the invention.

Moreover, the reduction in gate leakage current improves the noise level.

Although the GaAs is mismatched on InP the small required thickness of GaAs can easily be grown with a good material quality.

The FET may in particular include a spacer layer immediately above the channel semiconductor material layer; and a delta-doped layer immediately above the spacer layer; wherein the Schottky semiconductor material layer is above the delta-doped layer. The spacer layer, delta doped layer and Schottky material layer may be considered together as a barrier layer, and may in particular all be formed of the second semiconductor material.

The spacer layer may be of the second semiconductor material.

Alternatively, a thicker doped layer may be used.

The FET may further include a buffer semiconductor material layer between the substrate and the channel.

In another aspect the invention relates to a method of manufacturing a heterojunction field effect transistor, comprising:

providing a substrate;

depositing a channel semiconductor material layer of a first semiconductor material above the first major surface for forming a channel;

depositing a Schottky semiconductor material layer of a second semiconductor material above the channel, the band gap of the second semiconductor material being greater than that of the first semiconductor material; and

depositing a metal gate layer above the Schottky semiconductor material layer forming a Schottky barrier with the Schottky semiconductor material layer;

characterized by depositing a strained semiconductor layer of a third semiconductor material having a higher Schottky barrier height than the second semiconductor material layer between the metal gate layer and the Schottky semiconductor material layer.

Note that in this specification the term “above” is intended to refer to materials deposited on the side of the first major surface and is not intended to imply any particular orientation of the HFET in space.

For a better understanding of the invention, an embodiment will now be described, purely by way of example, with reference to the accompanying drawings in which:

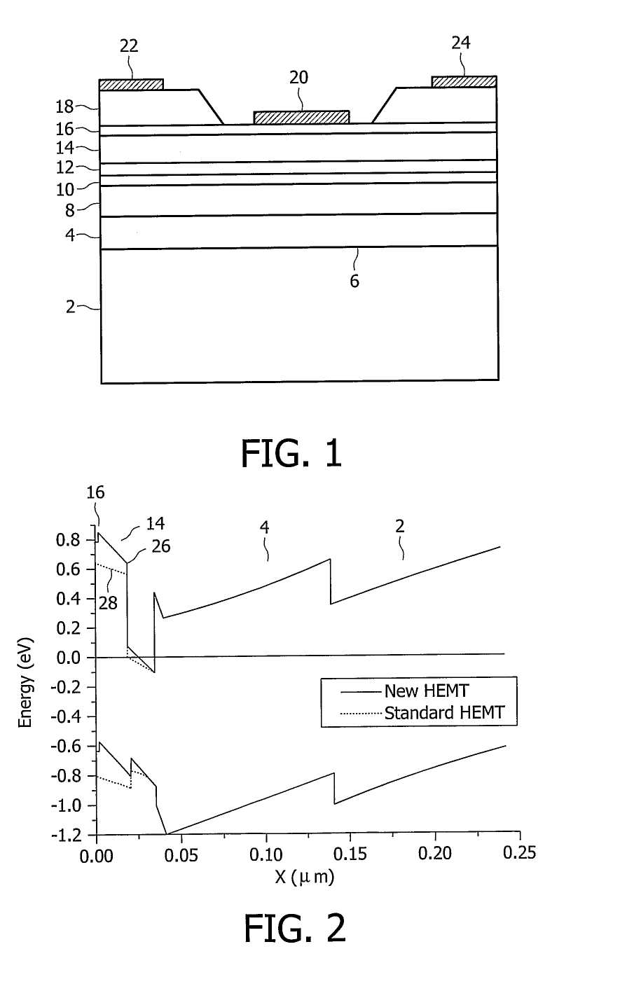

FIG. 1 is a cross section through a first embodiment of the invention; and

FIG. 2 shows a band diagram of the FET of FIG. 1.

The figures are schematic and not to scale.

Referring to FIG. 1, an InP substrate 2 has a buffer semiconductor layer 4 of Al_{0.48}In_{0.52}As lattice matched to the InP substrate on its first major surface 6. Above that is a channel semiconductor layer 8 of GaInAs.

Above the channel is provided firstly a thin spacer layer 10 of AlInAs, again Al_{0.48}In_{0.52}As so as to be lattice matched, followed by a highly n+ type delta-doped layer 12 and then a Schottky barrier layer 14 again of Al_{0.48}In_{0.52}As.

Above the Schottky barrier layer 14 is provided a thin, 2 nm thick high electron affinity layer 16 of GaAs. GaAs provides a higher electron affinity and Schottky barrier height than the Al_{0.48}In_{0.52}As Schottky barrier layer 14. In alterative embodiments an alternative semiconductor with higher electron affinity and Schottky barrier height may be used. The layer is not lattice matched to InP and so the GaAs layer 16 is strained. However, since the GaAs layer 16 is so thin it can be readily grown to be of high quality. Note that the term “high electron affinity” means in this context a higher electron affinity than the Schottky barrier layer 14.

A cap layer 18 of highly doped GaInAs is provided above the thin high electron affinity layer 16. The cap layer is recessed to expose the high electron affinity layer 16 in the gate region.

A metallic gate contact 20, in the example of titanium, though gold is an alternative, is made to the high electron affinity layer 16. Source 22 and drain 24 contacts are made to the cap layer.

This structure can be made on an InP substrate simply by depositing the layer in the order above onto the substrate. The layers can be grown by any known process, for example MBE or MOCVD or any of the many other semiconductor growth and doping processes known to those skilled in the art.

The structure may be formed into a HFET, in particular a HEMT, and the skilled person will realise that to finish the HEMT as a number of steps are required. The skilled person will be aware of how these may be carried out and so for simplicity a detailed description of these steps will be omitted.

FIG. 2 shows the band structure achieved of the device according to the invention (26, full line) and a comparative example (28, dotted line) which is identical except that the GaAs layer 16 is omitted. The OV level is the Fermi level, and in particular the Fermi level in the metal layer 20.

It will be noted that the Schottky barrier height provided in the embodiment is 0.8V (see the location of the conduction band edge at x=0.00), compared with 0.65V in the prior art. Note in this connection that the higher electron affinity of GaAs compared with AlInAs effectively adds a small step of 0.1 eV to the conduction band at the GaAs—AlInAs boundary which effectively is added to the Schottky barrier height.

Because the GaAs layer 16 does not contain aluminium it is less susceptible to oxidation than in prior art devices which increases reliability. This is especially true in regions around the gate. Also, better selective etches for InGaAs on GaAs exist than for InGaAs on AlInAs, so selective etching of the cap layer of InGaAs becomes easier.

A large forward swing can be achieved for an enhancement mode HEMT in accordance with the invention.

The embodiment can achieve a large reduction in gate leakage current.

The invention is not limited to the example set out above and the skilled person will be aware of different semiconductor materials that may be used. The invention can be applied to all FET-type devices, including both p-type and n-type devices.

From reading the present disclosure, other variations and modifications will be apparent to persons skilled in the art. Such variations and modifications may involve equivalent and other features which are already known in the design, manufacture and use of semiconductors and which may be used in addition to or instead of features described herein. Although claims have been formulated in this application to particular combinations of features, it should be understood that the scope of disclosure also includes any novel feature or any novel combination of features disclosed herein either explicitly or implicitly or any generalisation thereof, whether or not it mitigates any or all of the same technical problems as does the present invention. The applicants hereby give notice that new claims may be formulated to any such features and/or combinations of such features during the prosecution of the present application or of any further applications derived therefrom.

1. A heterojunction field effect transistor (FET), comprising:
a substrate (2) having a first major surface;
a channel (8) semiconductor material layer of a first semiconductor material above the first major surface for forming a channel;
a Schottky semiconductor material layer (14) of a second semiconductor material above the channel, the band gap of the second semiconductor material (14) being greater than that of the first semiconductor material (8); and
a metal gate layer (20) above the Schottky semiconductor material layer forming a Schottky barrier with the Schottky semiconductor material layer;
characterized by an intermediate semiconductor layer (16) of a third semiconductor material between the metal gate layer (20) and the Schottky semiconductor material layer (14), the third semiconductor material having a higher Schottky barrier height with the metal gate layer (20) than the second semiconductor material layer.

2. A FET according to claim 1 wherein the thickness of the intermediate semiconductor layer (16) is in the range 2 nm to 6 nm.

3. A FET according to claim 1 further comprising a cap layer (18) formed on the intermediate semiconductor layer,

4. A FET according to claim 1 wherein the first semiconductor material (8) is GaInAs and the second semiconductor material layer (14) is of AlInAs.

5. A FET according to claim 4 wherein the third semiconductor material layer (16) is of GaAs.

6. A FET according to claim 4 wherein the substrate (2) is of InP or GaAs.

7. A heterojunction field effect transistor according to claim 1, comprising:
a spacer layer (10) immediately above the channel semiconductor material layer (8); and
a delta-doped layer (12) immediately above the spacer layer (10);
wherein the Schottky semiconductor material layer (14) is above the delta-doped layer (12).

8. A FET according to claim 7 wherein the spacer layer (10) is of the second semiconductor material.

9. A FET according to claim 1 further comprising a buffer (4) semiconductor material layer between the substrate (2) and the channel semiconductor layer (8).

10. A method of manufacturing a heterojunction field effect transistor, comprising:
providing a substrate (2) having a first major surface (6);
depositing a channel semiconductor material layer (8) of a first semiconductor material above the first major surface (6) for forming a channel;
depositing a Schottky semiconductor material layer (14) of a second semiconductor material above the channel, the band gap of the second semiconductor material (14) being greater than that of the first semiconductor material (8); and
depositing a metal gate layer (20) above the Schottky semiconductor material layer forming a Schottky barrier with the Schottky semiconductor material layer (14);
characterized by depositing a strained semiconductor layer (16) of a third semiconductor material having a higher Schottky barrier height than the second semiconductor material layer between the metal gate layer (20) and the Schottky semiconductor material layer (14).
